(19) United States
(12) Patent Application Publication
(10) Pub. No.: US 2002/0179320 A1
(43) Pub. Date: Dec. 5, 2002

(54) Flexible conductive sheet

(75) Inventors: Yuet-Ying Yu, Hopewell Junction, NY (US); Charles Hendricks, Wappingers Falls, NY (US); Robert N. Wiggin, Poughkeepsie, NY (US)

Correspondence Address: Sean F. Sullivan, Cantor Colburn LLP, 55 Griffin Road South, Bloomfield, CT, 06002, US

(73) Assignee: INTERNATIONAL BUSINESS MACHINES CORPORATION, ARMONK, NY (US)

(21) Appl. No.: 09/872,882

(22) Filed: Jun. 1, 2001

(51) Int. Cl. H05K 1/00

(52) U.S. Cl. 174/254

(57) ABSTRACT

A flexible conductive sheet is disclosed. In an exemplary embodiment of the invention, the flexible sheet includes a polyimide base layer and a metallic layer formed in a grid pattern upon the base layer. Preferably, there are a plurality of metallic layers, formed upon the base layer, with at least one of the plurality of metallic layers formed in the grid pattern. The metallic layers further include an adhesion layer, the adhesion layer further comprising a chromium layer, applied upon the polyimide base layer, and a copper layer, formed upon the chromium layer. Finally, a nickel layer is formed upon the adhesion layer, and a gold layer is formed upon the nickel layer.

### BACKGROUND

The present invention relates generally to integrated circuit testing and, more particularly, to a flexible conductive sheet for use in electronic interconnection package (substrate) testing.

Integrated circuit chips may be packaged in a variety of ways, depending upon the performance and reliability requirements of the system in which they are used. High end integration schemes, sometimes referred to as multichip modules (MCM) or single chip modules (SCM), normally include at least one integrated circuit chip which is mounted to an insulating substrate. The insulating substrate, which may be ceramic, for example, has one or more wiring layers and thus provides a medium for electrical connections between chips (on an MCM) and/or between modules (for MCM or SCM). The wiring layers of the substrate are terminated at each of the top and bottom surfaces of the substrate in an array of I/O pads for interfacing to the chip and to a circuit board or other higher level module. The I/O pads may be a part of a controlled collapse chip contact (C4), ball grid array (BGA) or other connection scheme.

Substrates are typically tested prior to chip attachment in order to locate wiring errors or manufacturing defects. FIG. 1 illustrates an existing substrate tester 10. The substrate tester 10 includes a supporting base 12, upon which is mounted a first positioning means 14, and an I/O contact assembly 16. Disposed above the I/O contact assembly 16 is probe assembly 18 and a second positioning means 20. The substrate to be tested is received by the I/O contact assembly 16. The first positioning means 14 is movable in the x-y direction (i.e., horizontally) with respect to the I/O contact assembly 16 for aligning the I/O contact assembly 16 with the probe assembly 18. The second positioning means 20 allows movement of the probe assembly 18 in the z-direction (i.e., vertically) to raise and lower the probe assembly 18 with respect to the I/O contact assembly 16. Controllers 22 provide signals to control the movement of first and second positioning means 14 and 20, as well as apply test signals to the substrate through the I/O contact assembly 16 and/or probe assembly 18, and thereafter measure the results.

In FIG. 2, there is shown in further detail a portion of an exemplary conventional probe 30 for testing a substrate 26 that has an array of integrated circuit I/O pads, also called “chip I/O pads” 28. The probe 30 forms a part of the probe assembly 18 shown in FIG. 1 and has an array of probe pins 24 arranged to individually contact the chip I/O pads 28. The I/O contact assembly 16 contacts the I/O pads (not visible in FIG. 2) on the underside of the substrate 26. In order to test for shorts/opens in the substrate 26, predetermined voltage levels are selectively applied to the I/O pads on the underside of the substrate 26 via the I/O contact assembly 16. The output voltages at the chip I/O pads 28 are thereafter measured by the probe 30.

However, the probe assembly 18, while effective, is an expensive means of testing substrates 26. In addition, the spacing between chip I/O pads 28 may be as small as 75 micrometers (μm) for state of the art substrates, and will likely become even smaller in the future. Accordingly, the spacing between the probe pins 24 must be of a similarly small magnitude. Furthermore, the degree of accuracy to which the probe pins 24 must be located within the probe 30 is extremely high. Such accuracy is quite difficult to achieve for machined or molded articles, and thus the fabrication of the probe 30 and probe assembly 18 becomes even more expensive. Still a further expense results from the need for a customized probe for each type of substrate tested (e.g., the chip I/O pad array is unlikely to be identical for any two substrate designs). Additionally, aligning the probe to each substrate to be tested requires a precise aligning means, such as an optical alignment system, which can also add expense in terms of equipment cost and/or reduced throughput. If integrated into the substrate tester 10, such an alignment system significantly limits throughput.

Shorting pads have also been proposed as an alternative to the probe of FIG. 2, for the more limited purpose of testing for undesired opens in the substrate. A shorting pad is typically formed from a conductive material placed across a plurality of the chip I/O pads, in order to short them together during the test. However, shorting pads are not without their own drawbacks. The breakage of substrates is a recurring problem with certain type of shorting pads, such as those relying on a piece of conductive cloth stretched across a supporting frame or block to make the connection between chip I/O pads. This is a result of the excessive pressure used to provide sufficient electrical continuity between the chip I/O pads.

Another alternative to shorting pads and probe assemblies is to spread conductive paste on a substantially flat probe tip. However, the paste generally does not stay on the probe tip, thus requiring cleaning of each substrate tested as well as frequent reapplication of the paste to the probe tip. Still a further alternative has been to use conductive elastomer shorting pads, which alleviate breakage and are apparently cleaner than conductive paste. It has been found, however, that conductive elastomer shorting pads can leave behind a residue on the substrate, which residue is not easily removed. Specifically, the residue left behind can include metals, such as silver, which can cause reliability problems. These metals (particularly silver) can migrate over time, under certain voltage, temperature and humidity conditions. As a result, dendritic growths are formed, which can bridge across conductors (e.g., chip I/O pads) normally electrically isolated, thus shorting together the conductors. In addition to metallic residue, the residue can also include oil, such as silicone oil, which makes the I/O pads non-wettable, thus rendering the substrate unusable. In either case, the residue is extremely difficult to remove.

### BRIEF SUMMARY

The foregoing discussed drawbacks and deficiencies of the prior art are overcome or alleviated by a flexible conductive sheet. In an exemplary embodiment of the invention, the flexible sheet includes a polyimide base layer and a metallic layer formed in a grid pattern upon the base layer. Preferably, there are a plurality of metallic layers, formed upon the base layer, with at least one of the plurality of metallic layers formed in the grid pattern. The metallic layers further include an adhesion layer, the adhesion layer further comprising a chromium layer, applied upon the polyimide base layer, and a copper layer, formed upon the chromium layer. Finally, a nickel layer is formed upon the adhesion layer, and a gold layer is formed upon the nickel layer.

In a preferred embodiment, the polyimide base layer is about 8 to about 25 angstroms (Å) in thickness. The chromium layer is about 250 angstroms in thickness, while the copper layer is about 1,500 to about 2,500 angstroms in thickness. The nickel layer is about 20,000 angstroms in thickness, and the gold layer is about 350 to about 15,000 angstroms in thickness. Both the nickel and gold layers are formed upon the adhesion layer by plating in accordance with the grid pattern.

### BRIEF DESCRIPTION OF THE DRAWINGS

Referring to the exemplary drawings wherein like elements are numbered alike in the several Figures:

FIG. 1 is an existing substrate tester;

FIG. 2 is a perspective view of a portion of a conventional probe usable with the substrate tester shown in FIG. 1;

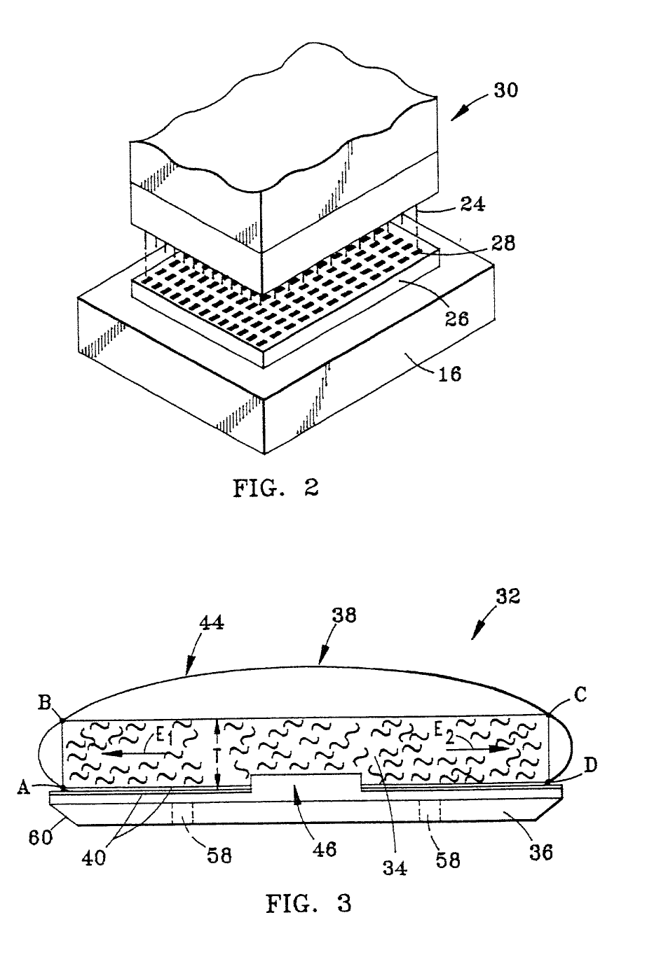

FIG. 3 is a cross-sectional view of a shorting pad probe tip assembly for use with a flexible conductive sheet;

FIG. 4 is a perspective view of a testing probe, including the shorting pad probe tip assembly shown in FIG. 3;

FIGS. 5(a) through 5(f) are cross sectional views illustrating the individual processing steps for a flexible conductive sheet, in accordance with an embodiment of the invention;

FIG. 6 is a perspective view of the sheet shown in FIG. 5(f);

FIGS. 7 through 9 are alternative embodiments of the sheet shown in FIG. 5(f); and

FIGS. 10 through 12 illustrate exemplary pattern configurations for the layers formed upon the disclosed embodiments of the flexible conductive sheet.

### DETAILED DESCRIPTION

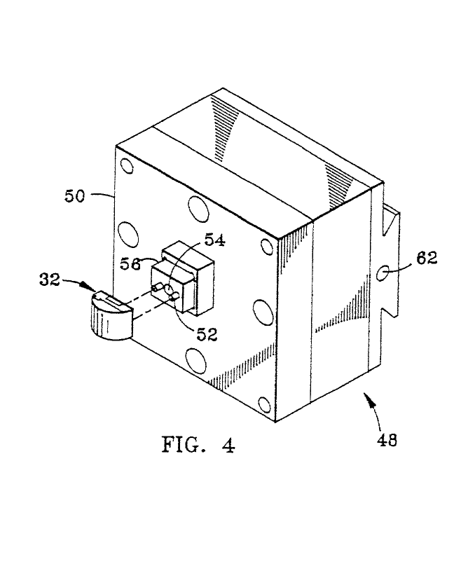

Referring initially to FIG. 3, there is shown a shorting pad probe tip assembly 32 used in accordance with the foregoing described embodiments of the present invention. The probe tip assembly 32 includes a compliant mandrel 34, a nest plate 36, and a flexible conductive sheet 38. The flexible conductive sheet 38, which is described in further detail hereinafter, is loosely wrapped around the compliant mandrel 34. The compliant mandrel 34 and flexible conductive sheet 38 are secured together to the supporting nest plate 36. At least one side 44 of the flexible conductive sheet 38 is electrically conductive, which side 44 is facing out as shown in FIG. 3.

The compliant mandrel 34 is preferably formed from an elastomeric material, such as rubber, urethane or foam, so that the probe tip assembly 32 returns to its original shape after undergoing mechanical compression. More preferably, the compliant mandrel 34 is made of Poron® Urethane, commercially available from Rogers Corporation, located in East Woodstock, Conn. The Poron® Urethane is preferred because it has superior resilience and no tackiness has been experienced therewith.

The nest plate 36 supports the compliant mandrel 34 and provides a mechanism to attach the probe tip 32 to the probe assembly (not shown in FIG. 3). Nest plate 36 may also have a feature 46 for locating the compliant mandrel 34 and for limiting any unintentional slippage of the mandrel 34. The nest plate 36 can be made from a relatively rigid material. Metals or engineering plastics are preferable for their strength and convenience. In addition, it is also preferable that the material be ferromagnetic, as will become apparent hereinafter. Gauge stock steel has been found to be a conveniently available and workable material, having the desired attributes of strength and ferromagnetism.

The flexible conductive sheet 38 may be secured to the compliant mandrel 34 by any of a variety of convenient methods, such as clips, screws or other fasteners (not specifically shown). Preferably, the flexible conductive sheet 38 is secured to the compliant mandrel 34 by an adhesive 40, such as an epoxy or glue, and still more preferably by double-sided tape, so as to make the sheet 38 replaceable and to make adjusting the slack of the conductive sheet 38 more convenient. The assembled flexible conductive sheet 38 and compliant mandrel 34 can be secured to the nest plate 36 in a similar manner.

As previously discussed, the flexible conductive sheet 38 is wrapped loosely around compliant mandrel 34 and has an amount of slack measured by the difference in the length L of flexible sheet that spans from one side of the compliant mandrel to the other side of the compliant mandrel 34 (e.g., point A to point D in FIG. 3) and the outer perimeter P of the compliant mandrel between the same two points (where P =AB+BC+CD). The amount of slack S in the loosely wrapped conductive sheet is determined by the degree to which the compliant mandrel expands in the lateral direction, as indicated by arrows E₁ and E₂ when under compression. In general, elastomeric materials may expand laterally by 30-120% of the thickness of the material. It is desirable that the slack S be of an amount sufficient that the compliant mandrel 34 can expand without putting the flexible conductive sheet 38 in tension. For example, with a compliant mandrel 34 made of a material that has a thickness T and that expands by 30% of the thickness, the length L desired for the flexible sheet would be greater than or equal to the sum: AB+BC+CD+0.3 T, thus providing a slack amount of S=0.3 T.

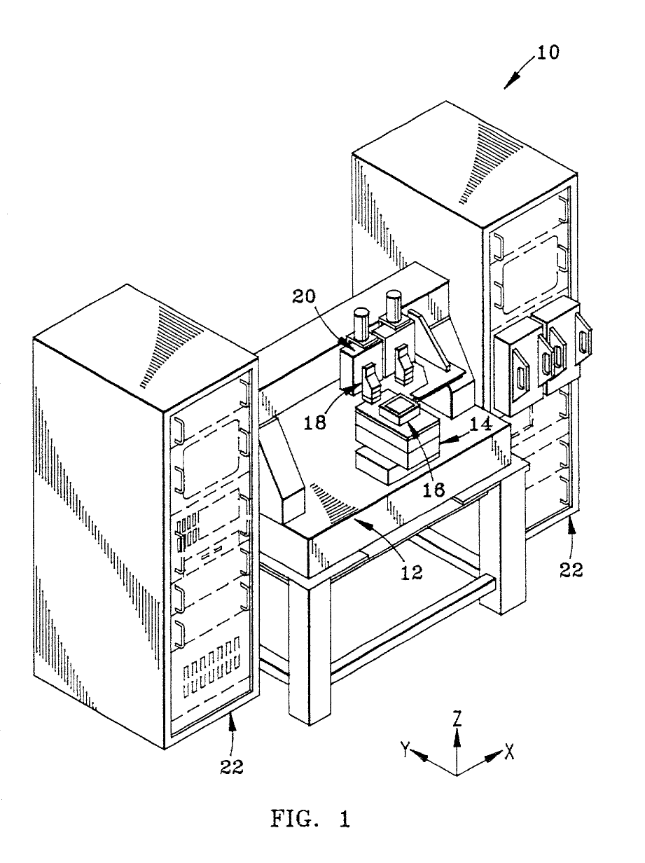

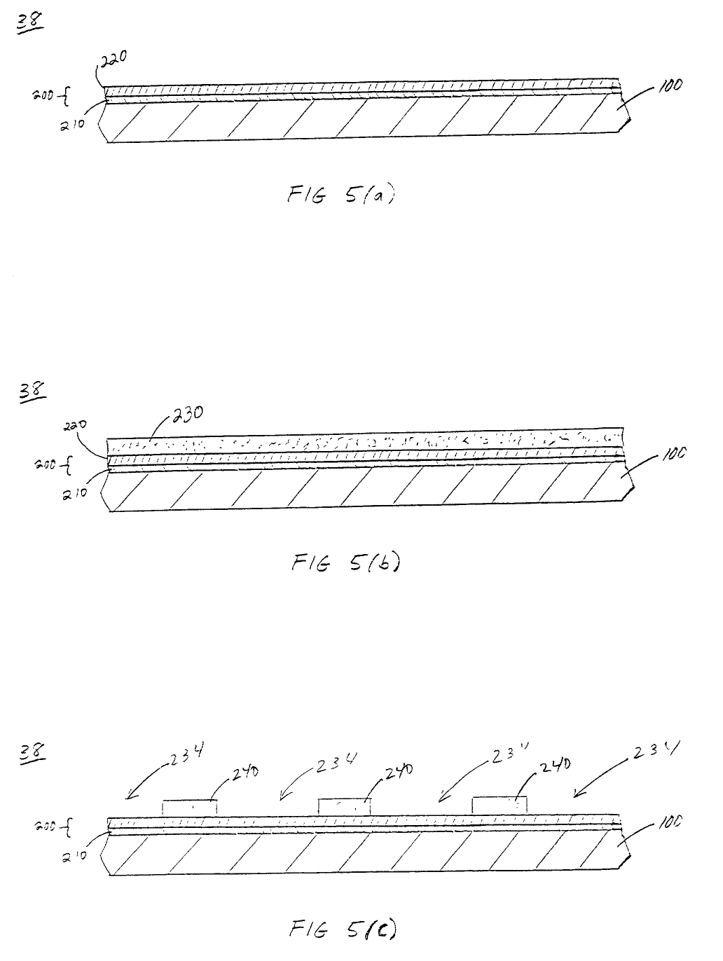

Referring now to FIG. 4, there is shown an exemplary embodiment of a probe 48 employing the shorting pad probe tip assembly 32. The probe 48 includes a probe block 50 adapted for coupling to a substrate tester, for example, one similar to that described in FIG. 1. A z-motion block 56 is mounted on the probe block 50, which z-motion block 56 provides for a relatively small degree of motion in the z-direction and applies a positive controlled force on the substrate under test. For example, the z-motion block 56 may include an air cylinder (not shown) coupled by air inlet 62, which air inlet 62 provides a passage for air to travel from the outside of the probe 48 through the probe material to the z-motion block 56, to a switch located in an external controller. Alternatively, a spring mechanism could also be used. The z-motion block 56 also includes a means for coupling the z-motion block 56 to the shorting pad probe tip assembly 32. A pair of locating pins 52 extend from the bottom of the z-motion block 56 for mating to a matching pair of holes 58 in the nest plate 36 of the shorting pad probe tip assembly 32 (FIG. 3). A magnet 54 mounted to the z-motion block 56 holds in position the nest plate 36, which nest plate 36 is ferromagnetic in this embodiment. The shorting pad probe tip assembly 32 can be removed from the z-motion block 56 by prying. The edges 60 of the nest plate 36 are tapered to facilitate such removal.

The probe 48 may also be incorporated into a substrate tester similar to the substrate tester 10 shown in FIG. 1, in order to test for opens in the substrate. A substrate is first inserted into the I/O contact assembly 16. The first positioning means 14 moves the I/O contact assembly 16 and substrate from a loading position to a test position such that the substrate is aligned with and located beneath the probe assembly 18. The second positioning means 20 moves probe assembly 18, including probe 48, towards the substrate such that the flexible conductive sheet 38 is facing the substrate.

The z-motion block 56 of the probe 48 is then activated to move the shorting pad probe tip assembly 32 further downwards towards the substrate, such that the flexible conductive sheet contacts the substrate surface. At this point of the downward motion, the compliant mandrel 34 has not come in contact with the substrate; the flexible conductive sheet 38, while in contact with the substrate, is freely moveable due to the slack provided therein. As the probe 48 continues to move downward, the compliant mandrel 34 contacts the flexible conductive sheet 38 and substrate and begins to compress under the force against the substrate. Because the slack provided in the way the flexible conductive sheet 38 is wrapped, the compliant mandrel is free to expand laterally under the compressive force. Thus, the flexible conductive sheet 38 and compliant mandrel 34 conform to the chip I/O pads, shorting together the first plurality of chip I/O pads.

Next, a voltage is applied to one or more of the I/O pads on the underside of the substrate through I/O contact assembly 16 and a voltage is measured at one or more of the chip I/O pads on the underside of the substrate. If the measured voltage is different than the applied voltage, that indicates that there is an open circuit in the substrate. After the voltage is measured, the probe 48 is raised, thus allowing the shorting pad probe tip 32 to return to its original shape such that it is ready for contacting a new substrate, and the I/O contact assembly 16 is moved to the loading position so that a new substrate may be tested. Further details regarding the probe 48 and the shorting pad probe tip assembly 32 may be found in U.S. Pat. Nos. 5,898,311 and 5,900,316, which are incorporated herein by reference.

The combination of the properties of the flexible conductive sheet 38 and the compliant mandrel 34 make the present invention advantageous for testing substrates. Because the flexible conductive sheet 38 is wrapped loosely around the compliant mandrel 34, the flexible conductive sheet 38 is free to move with respect to the compliant mandrel 34 during compression from testing. Because the compliant mandrel has good energy absorption and excellent resilience, particularly when Poron® Urethane is used, the flexible conductive sheet 38 makes conformal contact with the chip I/O array of the substrate with relatively low compressive forces, thus providing a uniformly good and repeatable contact with all the I/O pads. In addition, the compliant mandrel 34 and flexible conductive sheet 38 are durable, usable through many repetitions and can be used for a variety of substrates, thus improving throughput on the substrate tester.

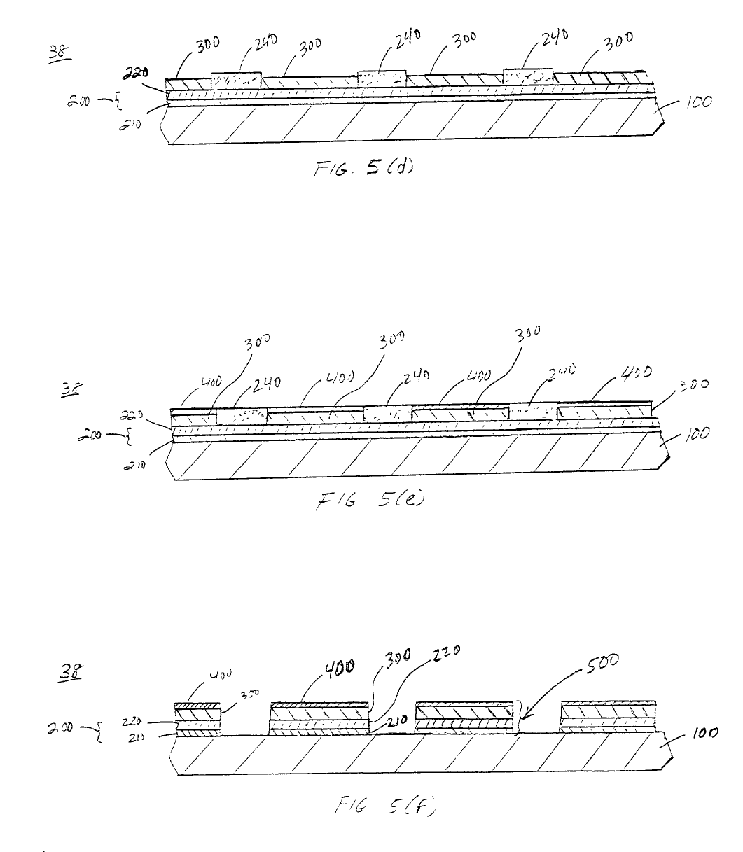

FIGS. 5-12 illustrate various aspects of detailed embodiments of the flexible conductive sheet 38, in accordance with the present invention, which embodiments are now described in further detail below.

Referring first to FIGS. 5(a) -5(f), the fabrication process for an exemplary embodiment of the flexible conductive sheet 38 is illustrated. The flexible conductive sheet 38 includes a flexible base layer 100, which is preferably a polymeric film. The film may comprise a pre-rolled polyimide sheet, such as Kapton® Polyimide Film, manufactured by the Du Pont Company or, more preferably, a spun-on polyimide. The thickness of the base layer 100 may range from about 8 to about 25 μm, and is preferably about 18 μm in thickness. However, if the base layer 100 is too thin, it cannot provide adequate support to the overlying metallic layers. On the other hand, if the base layer 100 is too thick, the flexible conductive sheet 38 may not have the desired flexibility. The base layer 100 is designed to support several layers thereupon, preferably metallic, which cooperate to provide adhesion to the polyimide film, as well as stress reduction and/or electrical conductivity.

An adhesion layer 200 is first applied to the base layer 100, the adhesion layer 200 further including a chromium (Cr) layer 210 of about 250 Å in thickness, followed by a copper (Cu) layer 220 of about 2,500 Å in thickness. The chromium layer 210 in the adhesion layer 200 provides adhesion of subsequent layers to the base layer 200, while the copper layer 220 is used as a softening agent to reduce stress in adjacent layers. Both the chromium layer 210 and the copper layer 220 of adhesion layer 200 may be deposited by sputtering or, more preferably, by evaporation techniques. Next, as shown in FIG. 5(b), a layer of photoresist 230 is deposited atop the adhesion layer 200. The photoresist is used to define a grid pattern, which grid pattern is subsequently used to enhance the flexibility of sheet 38, as described in further detail later.

In FIG. 5(c), portions of photoresist layer 230 are removed after implementing photolithographic techniques such as masking and etching, thereby defining a grid opening pattern 234, into which subsequent metallic layers are deposited. The remaining blocks 240 of photoresist will be subsequently removed after all of the metallic layers are formed, in order to define the openings within the metallic grid.

Referring now to FIG. 5(d), a layer 300 of nickel is formed atop the adhesion layer 200, preferably by plating, and in accordance with the grid opening pattern 234. The nickel layer 300 is about 20,000 to about 25,000 Å in thickness, and provides a diffusion barrier between the copper layer 200 and a fourth layer 400 of gold (Au), shown in FIG. 5(e). The gold layer 400 is formed atop the nickel layer 300 in the same plated grid pattern as the nickel layer. Alternatively, the gold layer 400 may be evaporated in a blanket fashion over the entire surface of sheet 38, as shown later. The gold layer 400 is about 500 to about 15,000 Å in thickness, and protects the underlying layers from oxidation, as well as provides low contact resistance.

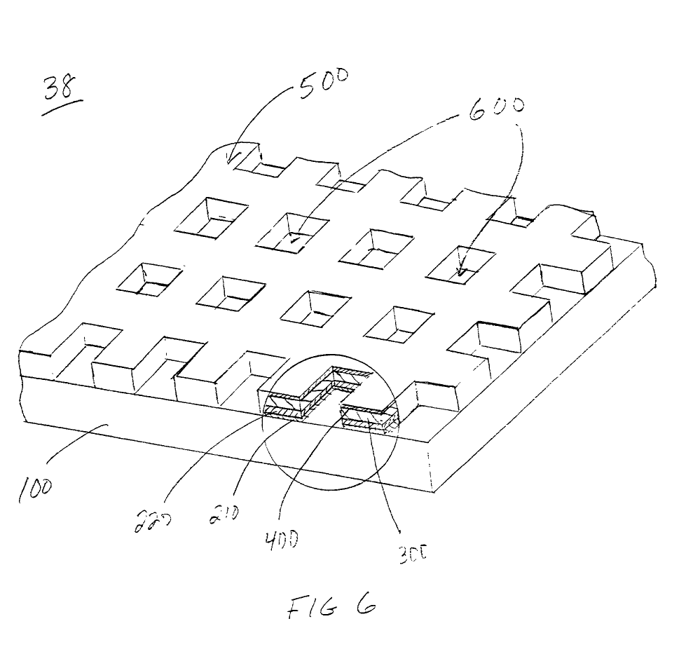

FIG. 5(f) illustrates the final step in the formation of the exemplary embodiment of the flexible sheet 38. In addition to the remaining blocks of photoresist 240, the portions of layers 210 and 220 there underneath are etched away, in conformance with the grid pattern of layers 300 and 400. As a result, the base layer 100 is left a with completed conductive metallic layer 500 formed in rectangularly shaped, grid pattern thereupon. An exemplary view of the completed metallic layer 500 is shown in FIG. 6. It will be noted that only that portion of the of sheet 38 within the circled area illustrates the individual metal layers within the completed metallic layer 500. Further, it will also be seen that the openings 600 left within completed metallic layer 500 create an added flexibility and degree of freedom of movement with layer 500. Accordingly, the overall result is a greater degree of electrical and mechanical contact between sheet 38 and a substrate.

The sheet 38, thus formed in accordance with the above described embodiment, enables good, reliable electrical connections to substrate topographies which may not necessarily be coplanar with one another. Since the flexible sheet 38 has conducting surfaces (e.g., gold layer 400) which more closely conform to the topography of a substrate surface, as compared to a uniform planar conductive surface, more accurate electrical test results are obtained.

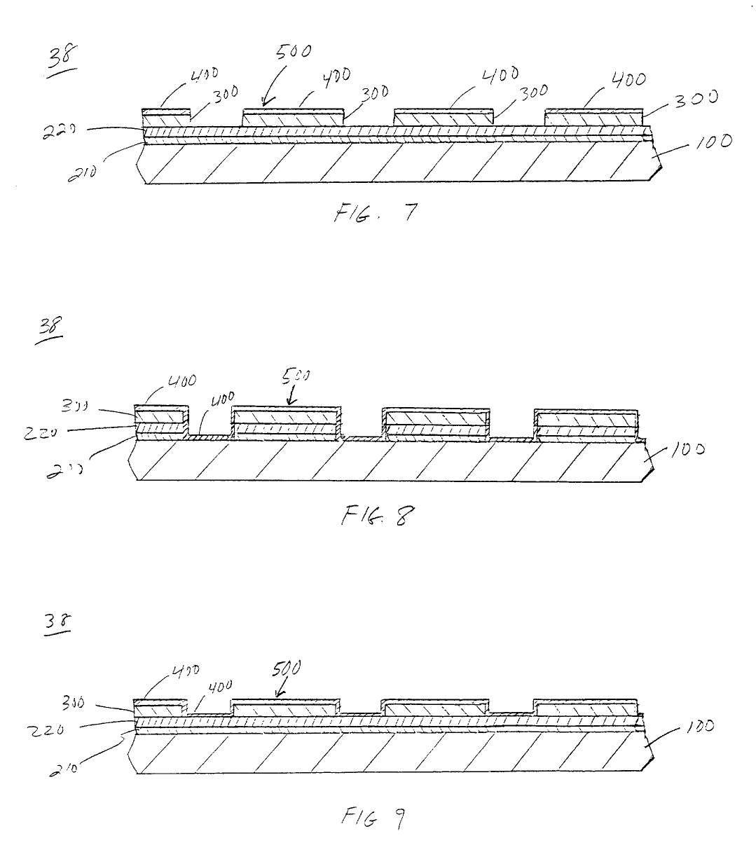

Referring now to FIGS. 7 through 9, there are shown alternative embodiments for the flexible sheet 38. In FIG. 7, the sheet 38 is completed after the removal of the photoresist blocks 234 only. Layers 210 and 220 are not etched, and hence remain in substantially a planar form. As a result, that portion of completed metallic layer 500 conforming to the grid pattern is thinner. In FIG. 8, layers 210 and 220 are etched away along with the photoresist blocks 234 in accordance with the grid pattern, but the etching is carried out prior to the formation of the gold layer 400. Then, the gold layer 400 is applied in a blanket fashion over the entire surface of sheet 38, such as by evaporation. In FIG. 9, neither layer 210 nor 220 is etched, and the gold layer 400 is applied in a blanket fashion after photoresist blocks 234 are removed. With regard to flexibility, however, the embodiment of FIG. 5(f) is most preferred, since all of the layers subsequently formed upon the base layer 100 are in conformance with the grid pattern.

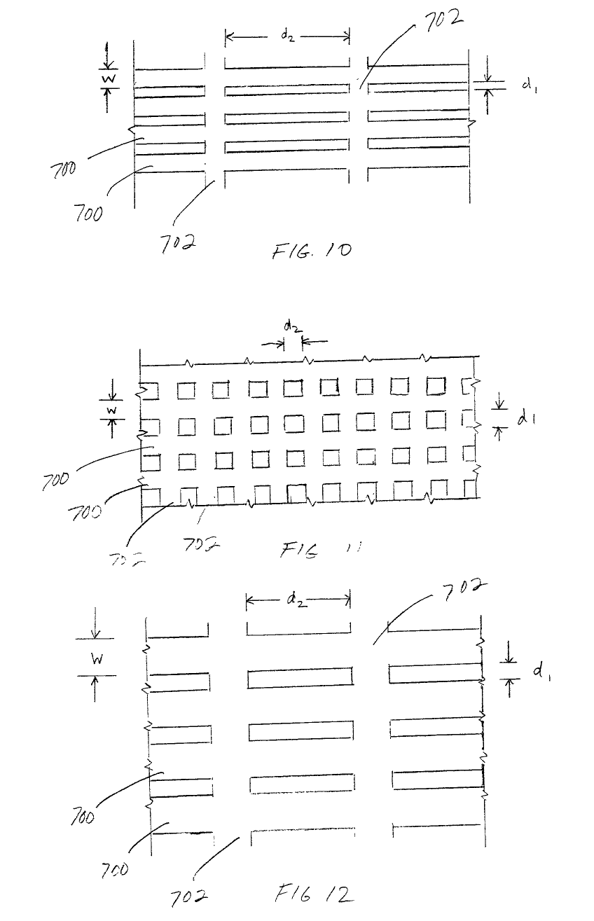

Finally, FIGS. 10 through 12 illustrate exemplary configurations of grid patterns which may be used in forming one or more of the metallic layers within final layer 500. In each of the configurations, there is a series of horizontally oriented strips 700 and a series of vertically oriented strips 702 that intersect with one another. In FIG. 10, each horizontal and vertical strip 700, 702 has a width, w, which is about 25 μm. In this embodiment, the horizontal strips 700 are more closely spaced together with respect to one another, having a separation distance d₁ of about 15 μm. The vertically oriented strips 702, however, have a separation distance d₂ of about 1 mm.

The grid pattern illustrated in FIG. 11 is the one shown in the exemplary embodiment of FIG. 6. Both the horizontal and vertical strips 700, 702 are separated by a equal distance d₁=d₂, or about 25 μm. Finally, in FIG. 12, the strips have a width, w, of about 50 μm. The horizontally oriented strips 700 are separated by about 25 μm from one another, while the vertically oriented strips 702 are separated by about 1 mm from one another. Regardless of the pattern used to form one or more of the metallic layers, it will be appreciated that the width and the spacing of the horizontally and vertically oriented strips may have a variety of values.

While the invention has been described with reference to a preferred embodiment, it will be understood by those skilled in the art that various changes may be made and equivalents may be substituted for elements thereof without departing from the scope of the invention. In addition, many modifications may be made to adapt a particular situation or material to the teachings of the invention without departing from the essential scope thereof. Therefore, it is intended that the invention not be limited to the particular embodiment disclosed as the best mode contemplated for carrying out this invention, but that the invention will include all embodiments falling within the scope of the appended claims.

What is claimed is:

1. A flexible sheet, comprising:
a polyimide base layer; and
a metallic layer formed in a grid pattern upon said base layer.

2. The flexible sheet of claim 1, further comprising:
a plurality of metallic layers, formed upon said base layer, at least one of said plurality of metallic layers formed in said grid pattern.

3. The flexible sheet of claim 2, wherein said plurality of metallic layers further comprise:
an adhesion layer, said adhesion layer further comprising:
a chromium layer, applied upon said polyimide base layer; and
a copper layer, formed upon said chromium layer;
a nickel layer, formed upon said adhesion layer; and
a gold layer, formed upon said nickel layer.

4. The flexible sheet of claim 1, wherein said polyimide base layer is about 8 to about 25 angstroms (Å) in thickness.

5. The flexible sheet of claim 4, wherein said polyimide base layer is about 18 angstroms in thickness.

6. The flexible sheet of claim 3, wherein said chromium layer is about 250 angstroms in thickness.

7. The flexible sheet of claim 3, wherein said copper layer is about 1,500 to about 2,500 angstroms in thickness.

8. The flexible sheet of claim 3, wherein said nickel layer is about 20,000 angstroms in thickness.

9. The flexible sheet of claim 3, wherein said gold layer is about 350 to about 15,000 angstroms in thickness.

10. The flexible sheet of claim 3, wherein said nickel layer is formed upon said adhesion layer by plating in accordance with said grid pattern.

11. The flexible sheet of claim 10, wherein said gold layer is formed upon said nickel layer by plating in accordance with said grid pattern.

12. The flexible sheet of claim 11, wherein portions of said adhesion layer are removed such that remaining portions of said adhesion layer conform to said grid pattern.

13. The flexible sheet of claim 12, wherein said removed portions of said adhesion layer are removed by etching.

14. The flexible sheet of claim 10, wherein said gold layer is formed upon said nickel layer by evaporation thereon.

15. The flexible sheet of claim 10, wherein:
portions of said adhesion layer are removed such that remaining portions of said adhesion layer conform to said grid pattern; and
said gold layer is formed upon said nickel layer by evaporation thereon.

16. The flexible sheet of claim 15, wherein said removed portions of said adhesion layer are removed by etching.

17. The flexible sheet of claim 3, wherein said nickel layer provides a diffusion barrier between said adhesion layer and said gold layer.

18. The flexible sheet of claim 17, wherein said gold layer has low contact resistance.

19. The flexible sheet of claim 18, wherein said gold layer protects underlying layers from oxidation.

20. The flexible sheet of claim 1, wherein said grid pattern further comprises:
a plurality of horizontally oriented strips; and
a plurality of vertically oriented strips.

21. The flexible sheet of claim 20, wherein:
said plurality of horizontally and vertically oriented strips have a width of about 25 μm to about 50 μm.

22. The flexible sheet of claim 21, wherein:
said plurality of horizontally oriented strips are separated from one another by about 15 μm to about 25 μm.

23. The flexible sheet of claim 22, wherein:
said plurality of vertically oriented strips are separated from one another by about 25 μm to about 1 mm.

24. A method of forming a flexible sheet, comprising:
forming a polyimide base layer; and
depositing a metallic layer in a grid pattern upon said base layer.

25. The method of claim 24, further comprising:
depositing a plurality of metallic layers upon said base layer, at least one of said plurality of metallic layers formed in said grid pattern.

26. The method of claim 25, wherein said depositing a plurality of metallic layers further comprises:
forming an adhesion layer, said adhesion layer further comprising:
a chromium layer, applied upon said polyimide base layer; and
a copper layer, formed upon said chromium layer;
forming a nickel layer upon said adhesion layer; and
forming a gold layer upon said nickel layer.

27. The method of claim 24, wherein said polyimide base layer is about 8 to about 25 angstroms (Å) in thickness.

28. The method of claim 27, wherein said polyimide base layer is about 18 angstroms in thickness.

29. The method of claim 26, wherein said chromium layer is about 250 angstroms in thickness.

30. The method of claim 26, wherein said copper layer is about 1,500 to about 2,500 angstroms in thickness.

31. The method of claim 26, wherein said nickel layer is about 20,000 angstroms in thickness.

32. The method of claim 26, wherein said gold layer is about 350 to about 15,000 angstroms in thickness.

33. The method of claim 26, wherein said nickel layer is formed upon said adhesion layer by plating in accordance with said grid pattern.

34. The method of claim 33, wherein said gold layer is formed upon said nickel layer by plating in accordance with said grid pattern.

35. The method of claim 34, wherein portions of said adhesion layer are removed such that remaining portions of said adhesion layer conform to said grid pattern.

36. The method of claim 35, wherein said removed portions of said adhesion layer are removed by etching.

37. The method of claim 33, wherein said gold layer is formed upon said nickel layer by evaporation thereon.

38. The method of claim 33, wherein:
portions of said adhesion layer are removed such that remaining portions of said adhesion layer conform to said grid pattern; and
said gold layer is formed upon said nickel layer by evaporation thereon.

39. The method of claim 38, wherein said removed portions of said adhesion layer are removed by etching.

40. The method of claim 26, wherein said nickel layer provides a diffusion barrier between said adhesion layer and said gold layer.

41. The method of claim 40, wherein said gold layer has low contact resistance.

42. The method of claim 41, wherein said gold layer protects underlying layers from oxidation.

43. The method of claim 24, wherein said grid pattern further comprises:
a plurality of horizontally oriented strips; and
a plurality of vertically oriented strips.

44. The method of claim 43, wherein:
said plurality of horizontally and vertically oriented strips have a width of about 25 μm to about 50 μm.

45. The method of claim 44, wherein:
said plurality of horizontally oriented strips are separated from one another by about 15 μm to about 25 μm.

46. The method of claim 44, wherein:
said plurality of vertically oriented strips are separated from one another by about 25 μm to about 1 mm.
